(19) United States
(12) Patent Application Publication
(10) Pub. No.: US 2024/0377662 A1
(43) Pub. Date: Nov. 14, 2024

(54) OPTICAL DEVICES AND METHODS OF MANUFACTURE

(71) Applicant: Taiwan Semiconductor Manufacturing Co., Ltd., Hsinchu (TW)

(72) Inventors: Ming Lee, Taipei City (TW); Tien-Lin Shen, Taipei City (TW); Wei-Heng Lin, Taipei City (TW); Hsing-Kuo Hsia, Jhubei City (TW); Chen-Hua Yu, Hsinchu (TW)

(21) Appl. No.: 18/415,092

(22) Filed: Jan. 17, 2024

Related U.S. Application Data
(60) Provisional application No. 63/509,815, filed on Jun. 23, 2023.
(60) Provisional application No. 63/501,471, filed on May 11, 2023.

(51) Int. Cl. G02F 1/025; G02F 1/015

(52) U.S. Cl. CPC G02F 1/025; G02F 1/0154; G02F 2202/06; G02F 2202/104; G02F 2203/50

(57) ABSTRACT

An optical device and methods of manufacturing such optical devices are presented. In embodiments the optical device is a tunable beam splitter which is made by forming a first dopant region over a substrate, the first dopant region comprising a first waveguide and a second waveguide, depositing a cladding material over the first waveguide and the second waveguide, and forming a second dopant region overlying the first waveguide and the second waveguide, wherein the forming the second dopant region comprises forming a first region extending over both the first waveguide and the second waveguide, the first region having a constant concentration of a first dopant.

### PRIORITY CLAIM AND CROSS-REFERENCE

This application claims the benefit of U.S. Provisional Application No. 63/509,815, filed on Jun. 23, 2023 and U.S. Provisional Application No. 63/501,471, filed on May 11, 2023, which applications are hereby incorporated herein by reference.

### BACKGROUND

Electrical signaling and processing is one technique for signal transmission and processing. Optical signaling and processing have been used in increasingly more applications in recent years, particularly due to the use of optical fiber-related applications for signal transmission.

Optical signaling and processing are typically combined with electrical signaling and processing to provide full-fledged applications. For example, optical fibers may be used for long-range signal transmission, and electrical signals may be used for short-range signal transmission as well as processing and controlling. Accordingly, devices integrating long-range optical components and short-range electrical components are formed for the conversion between optical signals and electrical signals, as well as the processing of optical signals and electrical signals. Packages thus may include both optical (photonic) dies including optical devices and electronic dies including electronic devices.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a silicon on insulator substrate, in accordance with some embodiments.

FIG. 2 illustrates a patterning of a first active layer of optical devices, in accordance with some embodiments.

FIG. 3 illustrates a deposition of a first dielectric material, in accordance with some embodiments.

FIG. 4 illustrates a deposition of a material, in accordance with some embodiments.

FIG. 5 illustrates a patterning of the material, in accordance with some embodiments.

FIG. 6 illustrates a deposition of a second dielectric material, in accordance with some embodiments.

FIG. 7 illustrates a formation of openings, in accordance with some embodiments.

FIG. 8 illustrates a formation of first contacts and second contacts, in accordance with some embodiments.

FIG. 9 illustrates a top down view of a beam splitter, in accordance with some embodiments.

FIG. 10 illustrates a top down view of two beam splitters, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Embodiments will now be described with respect to particular embodiments in which a tunable beam splitter is formed with a common polysilicon material as a ground and forming signal contacts that are located outside of the polysilicon region. The embodiments described herein, however, are intended to be illustrative and are not intended to limit the embodiments to those precisely described herein as the ideas presented may be embodied within a wide variety of manners without departing from the scope of the ideas.

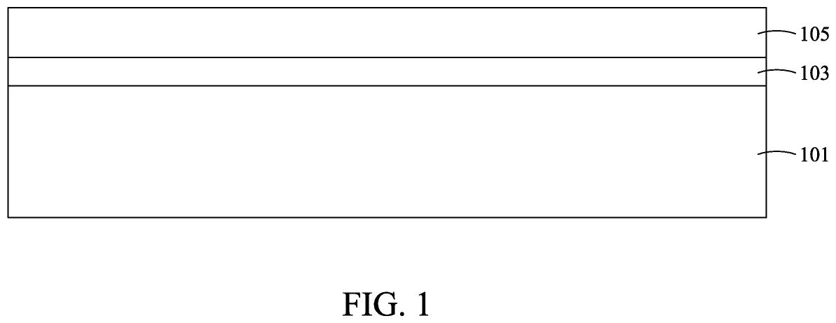

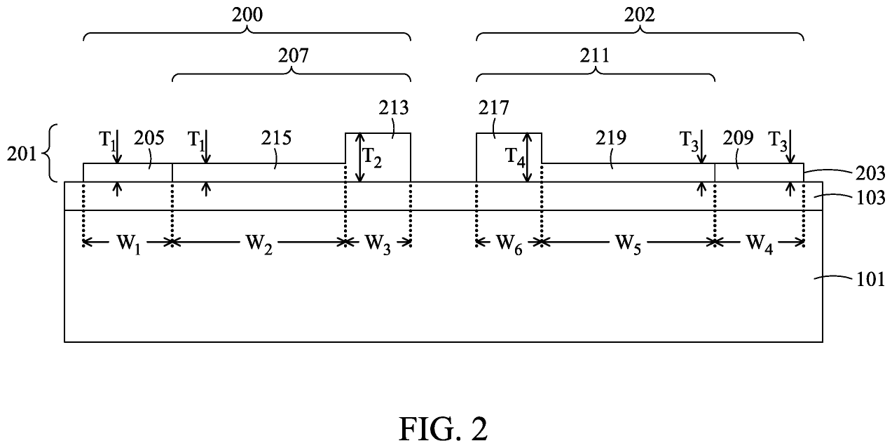

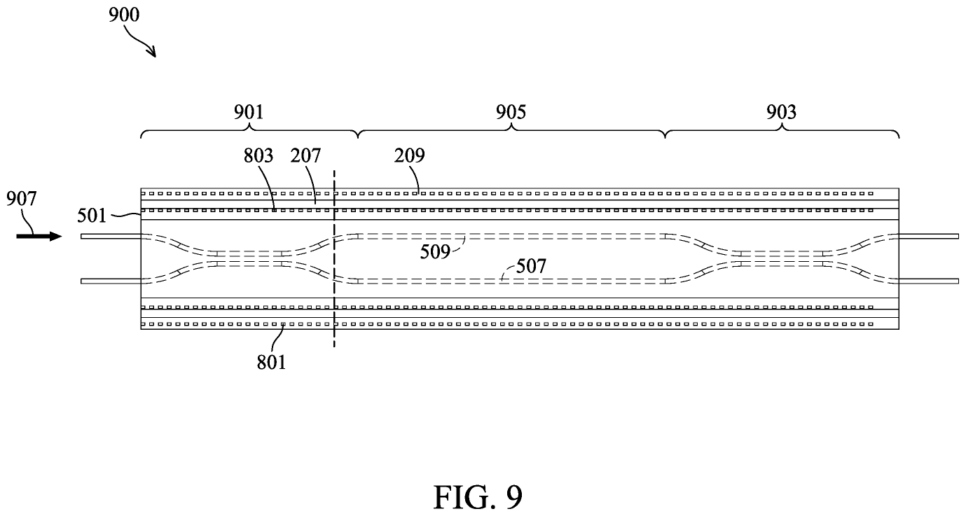

With reference now to FIG. 1, there is illustrated an initial structure used to form a tunable beam splitter 900 (not illustrated in final form in FIG. 1 but illustrated in a top down view below in FIG. 9), in accordance with some embodiments. In the particular embodiment illustrated in FIG. 1, the tunable beam splitter 900 is part of a photonic integrated circuit (PIC) which comprises at this stage in the manufacturing process a first substrate 101, a first insulator layer 103, and a layer of material 105 for a first active layer 201 of first optical components 203 (not separately illustrated in FIG. 1 but illustrated and discussed further below with respect to FIG. 2). In an embodiment, at a beginning of the manufacturing process of the tunable beam splitter 900, the first substrate 101, the first insulator layer 103, and the layer of material 105 for the first active layer 201 of first optical components 203 may collectively be part of a silicon-on-insulator (SOI) substrate. Looking first at the first substrate 101, the first substrate 101 may be a semiconductor material such as silicon or germanium, a dielectric material such as glass, or any other suitable material that allows for structural support of overlying devices.

The first insulator layer 103 may be a dielectric layer that separates the first substrate 101 from the overlying first active layer 201 and can additionally, in some embodiments, serve as a portion of cladding material that surrounds the subsequently manufactured first optical components 203 (discussed further below). In an embodiment the first insulator layer 103 may be silicon oxide, silicon nitride, germanium oxide, germanium nitride, combinations of these, or the like, formed using a method such as implantation (e.g., to form a buried oxide (BOX) layer) or else may be deposited onto the first substrate 101 using a deposition method such as chemical vapor deposition, atomic layer deposition, physical vapor deposition, combinations of these, or the like. However, any suitable material and method of manufacture may be used.

The material 105 for the first active layer 201 is initially (prior to patterning) a conformal layer of material that will be used to begin manufacturing the first active layer 201 of the first optical components 203. In an embodiment the material 105 for the first active layer 201 may be a translucent material that can be used as a core material for the desired first optical components 203, such as a semiconductor material such as silicon, germanium, silicon germanium, combinations of these, or the like, while in other embodiments the material 105 for the first active layer 201 may be a dielectric material such as silicon nitride or the like, although in other embodiments the material 105 for the first active layer 201 may be III-V materials, lithium niobate materials, or polymers. In embodiments in which the material 105 of the first active layer 201 is deposited, the material 105 for the first active layer 201 may be deposited using a method such as epitaxial growth, chemical vapor deposition, atomic layer deposition, physical vapor deposition, combinations of these, or the like. In other embodiments in which the first insulator layer 103 is formed using an implantation method, the material 105 of the first active layer 201 may initially be part of the first substrate 101 prior to the implantation process to form the first insulation layer 103. However, any suitable materials and methods of manufacture may be utilized to form the material 105 of the first active layer 201.

FIG. 2 illustrates a patterning and implantation of the material 105 in order to form the first optical components 203. In an embodiment the material 105 for the first active layer 201 may be patterned into the desired shapes for the first active layer 201 of first optical components 203 and in the particular embodiment illustrated in FIG. 2, the desired shape for a portion of the tunable beam splitter 900. In an embodiment the material 105 may be patterned using, e.g., one or more photolithographic masking and etching processes. However, any suitable method of patterning the material 105 may be utilized.

In the particular embodiment illustrated in FIG. 2 the material 105 for the first active layer 201 may be patterned into a first dopant region 200 and a second dopant region 202 separate from the first dopant region 200. In this embodiment the first dopant region 200 may further comprise a first region 205 and a second region 207 while the second dopant region 202 may further comprise a third region 209 and a fourth region 211. However, any suitable number of regions may be utilized.

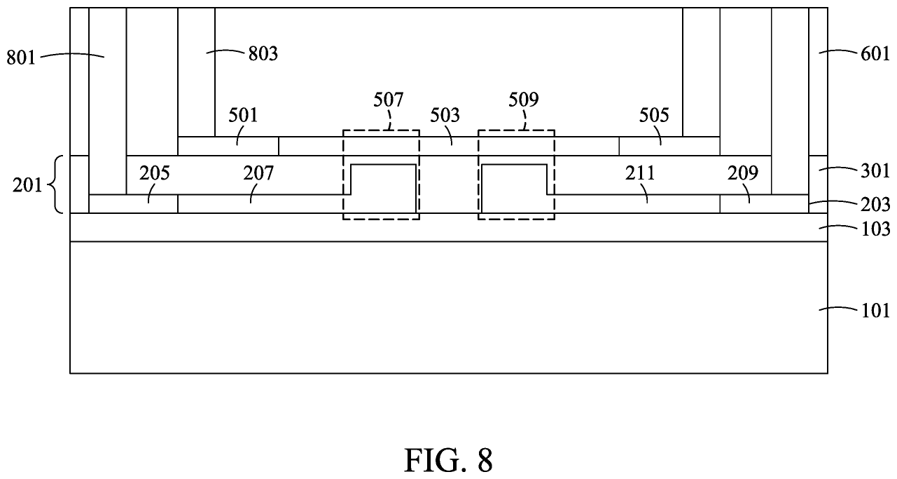

Looking first at the first region 205, the first region 205 may be patterned to provide a connection to a subsequently formed first contact 801 (not illustrated in FIG. 2 but illustrated below with respect to FIG. 8). As such, the first region 205 may be patterned to have a first thickness T₁ of between about 50 nm and about 100 nm. Additionally, the first region 205 may have a first width W₁ of between about 0.5 μm and about 1 μm. However, any suitable dimensions may be utilized.

Looking next at the second region 207, the second region 207 may be patterned to have a first waveguide region 213 and a first connecting region 215, wherein the first waveguide region 213 and the first connecting region 215 are illustrated in FIG. 2 as being separated by a dashed line but which may or not have an interface in the final device. In an embodiment the first connecting region 215 is utilized to provide electrical connection between the first region 205 and the first waveguide region 213, and may be formed to have the first thickness T₁ the same as the first region 205. Additionally, the first connecting region 215 may have a second width W₂ that is sufficient to separate the first waveguide region 213 from first contacts 801 (not illustrated in FIG. 2 but illustrated and described further below with respect to FIG. 8), such as being between about 0.5 μm and about 1 μm. However, any suitable dimensions may be utilized.

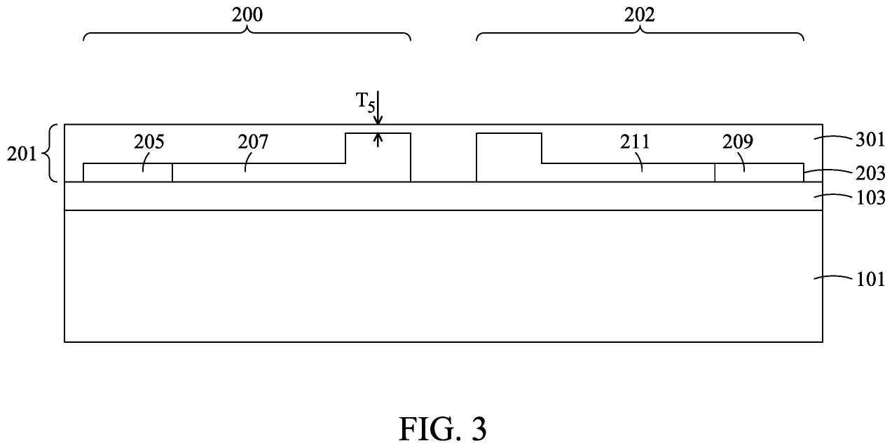

The first waveguide region 213 is connected to the first connecting region 215 and is formed to have dimensions that, along with the surrounding cladding material (e.g., the underlying first insulation layer 103 and overlying first dielectric material 301—not illustrated in FIG. 2 but illustrated and described further below with respect to FIG. 3) has total internal reflection to light passing through the first waveguide region 213. In a particular embodiment the first waveguide region 213 may be formed to have a second thickness T₂ larger than the first thickness T₁, such as having the second thickness T₂ of between about 150 nm and about 300 nm. Additionally, the first waveguide region 213 may have a third width W₃ of between about 50 nm and about 100 nm. However, any suitable dimensions may be utilized.

Looking next at the third region 209, the third region 209 may be patterned to provide a connection to a subsequently formed first contact 801 (not illustrated in FIG. 2 but illustrated below with respect to FIG. 8). As such, the third region 209 may be patterned to have a third thickness T₃ of between about 50 nm and about 150 nm. Additionally, the third region 209 may have a fourth width W₄ of between about 0.5 μm and about 1 μm. However, any suitable dimensions may be utilized.

Looking next at the fourth region 211, the fourth region 211 may be patterned to have a second waveguide region 217 and a second connecting region 219, wherein the second waveguide region 217 and the second connecting region 219 are illustrated in FIG. 2 as being separated by a dashed line but which may or not have an interface in the final device. In an embodiment the second connecting region 219 is utilized to provide electrical connection between the third region 209 and the second waveguide region 217, and may be formed to have the third thickness T₃ the same as the first region 205. Additionally, the second connecting region 219 may have a fifth width W₅ of between about 0.5 μm and about 1.5 μm. However, any suitable dimensions may be utilized.

The second waveguide region 217 is connected to the second connecting region 219 and is formed to have dimensions that, along with the surrounding cladding material (e.g., the underlying first insulation layer 103 and overlying first dielectric material 301—not illustrated in FIG. 2 but illustrated and described further below with respect to FIG. 3) has total internal reflection to light passing through the second waveguide region 217. In a particular embodiment the second waveguide region 217 may be formed to have a fourth thickness T₄ larger than the third thickness T₃, such as having the fourth thickness T₄ of between about 100 nm and about 250 nm. Additionally, the second waveguide region 217 may have a sixth width W₆ of between about 300 nm and about 500 nm. However, any suitable dimensions may be utilized.

Once the material 105 has been patterned, a first implantation process may be performed in order to implant first dopants into the first region 205, the second region 207, the third region 209 and the fourth region 211. In an embodiment the first implantation process may be two or more implantations which implant first dopants within the first region 205, the second region 207, the third region 209 and the fourth region 211. As such, while the precise first dopant may be dependent at least in part on the design of the tunable beam splitter 900, in some embodiments the first dopants may be a p-type dopant such as boron, gallium, or indium. However, any suitable dopants may be used.

In an embodiment the first dopants may be implanted using one of the implantations of the first implantation process, whereby ions of the desired first dopants are accelerated and directed towards first region 205, the second region 207, the third region 209 and the fourth region 211. The ion implantation process may utilize an accelerator system to accelerate ions of the desired first dopant at a first dosage concentration. As such, while the precise dosage concentration utilized will depend at least in part on the first region 205, the second region 207, the third region 209 and the fourth region 211, and the first dopants used, in one embodiment the accelerator system may utilize an energy of between about 100 eV and about 600 eV along with a dosage concentration of about 1E13 atoms/cm² to about 1E15 atoms/cm². However, any suitable parameters may be utilized.

Additionally, the first dopants may be implanted perpendicular to the first region 205, the second region 207, the third region 209 and the fourth region 211, or else at, e.g., an angle of between about 0° and about 60°, from perpendicular to the first region 205, the second region 207, the third region 209 and the fourth region 211 and may be implanted at a temperature of between about −20° C. and about 100° C. However, any suitable parameters may be utilized.

In one particular embodiment the first dopants are implanted within the second region 207 and the fourth region 211 in order to form P+ regions within the first connecting region 215, the first waveguide region 213, the second waveguide region 217, and the second connecting region 219. As such, the first dopants may have a concentration within the second region 207 and the fourth region 211 of between about 2e17 cm⁻³ and about 5e18 cm⁻³. However, any suitable concentration may be utilized.

One of the implantations of the first implantation process may also be used to implant the first dopants into the first region 205 and the third region 209 to prepare for subsequent connections to the first contacts 801. In this embodiment the first region 205 and the third region 209 may be implanted to form P++ regions. As such, in these embodiments the first region 205 and the third region 209 may comprise the first dopants at a concentration of between about 5e18 cm⁻³ and about 5e20 cm⁻³. However, any suitable concentrations may be utilized.

The first implantation process may be performed by any suitable number of implantations. For example, in one embodiment two separate implantations may be performed so that a first implantation implants the first dopants into the first region 205 and the third region 209 to form the P++ regions while a second implantation implants the first dopants into the second region 207 and the fourth region 211. In another embodiment two or more implantations may be performed so that a first implantation implants the first dopants into the first region 205, the second region 207, the third region 209, and the fourth region 211, while a second implantation implants additional first dopants into the first region 205 and the third region 209. Any suitable number of implants may be utilized, and all such implants are fully intended to be included within the scope of the embodiments.

FIG. 3 illustrates a deposition of a first dielectric material 301 over the first region 205, the second region 207, the third region 209, and the fourth region 211 (wherein the first waveguide region 213, the first connecting region 215, the second waveguide region 217, and the second connecting region 219 are not illustrated for clarity). In an embodiment the first dielectric material 301 may be a dielectric material such as silicon oxide, or a low-k dielectric material such as silicon oxynitride, combinations of these, or the like, deposited using a deposition process such as chemical vapor deposition, physical vapor deposition, atomic layer deposition, combinations of these, or the like, followed by a planarization process such as chemical mechanical polishing processes. However, any suitable materials and manufacturing processes may be utilized.

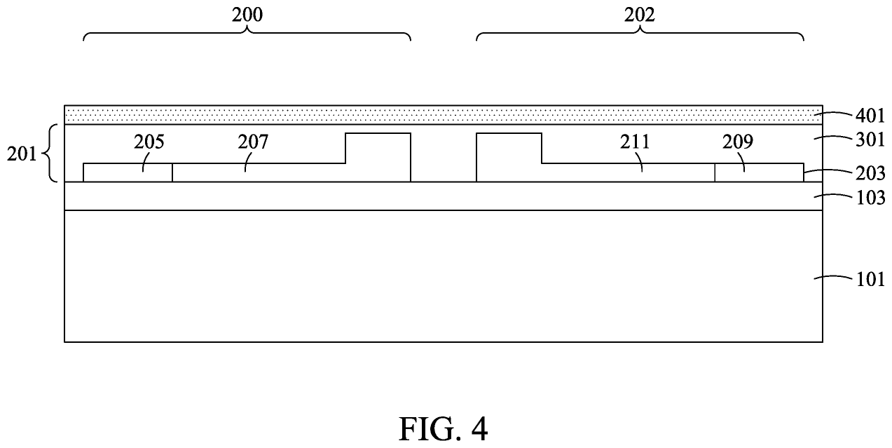

In an embodiment the first dielectric material 301 is utilized in order to provide further cladding material (along with the first insulator layer 103) in order to surround the first region 205, the second region 207, the third region 209, and the fourth region 211 and also to isolate the first region 205, the second region 207, the third region 209, and the fourth region 211 from overlying structures (not illustrated in FIG. 3 but illustrated and described further below with respect to FIG. 4). As such, in an embodiment the first dielectric material 301 may have a fifth thickness T₅ over the first waveguide region 213 and the second waveguide region 217 of between about 2 nm and about 10 nm. However, any suitable thickness may be utilized.

FIG. 4 illustrates deposition of a second material 401 over the first dielectric material 301. In an embodiment the second material 401 may a material that is similar to the material 105 (discussed above with respect to FIG. 1). In a particular embodiment the second material 401 may be a material such as silicon (e.g., polysilicon) deposited using a deposition process such as chemical vapor deposition, physical vapor deposition, the like, or combinations thereof. However, any suitable materials and methods of deposition may be utilized.

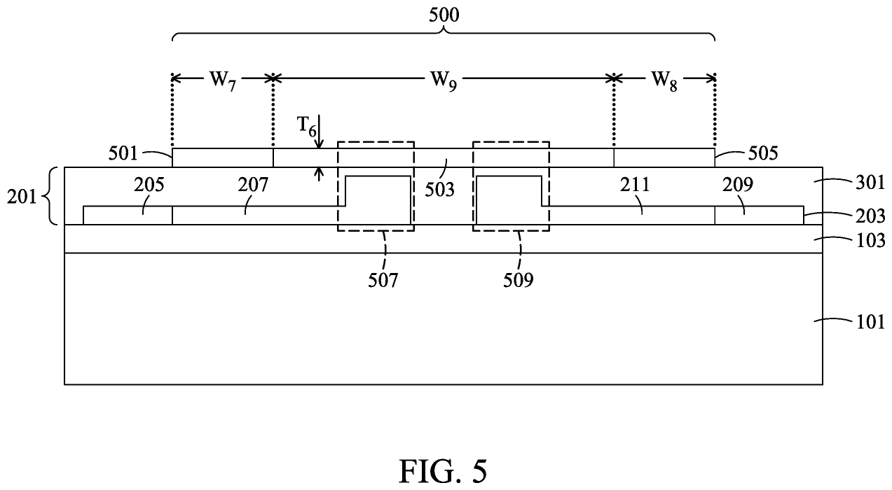

FIG. 5 illustrates a patterning and implantation of the second material 401. In an embodiment the second material 401 may be patterned into the desired shape for a portion of the tunable beam splitter 900. In an embodiment the second material 401 may be patterned using, e.g., one or more photolithographic masking and etching processes. However, any suitable method of patterning the second material 401 may be utilized.

In the embodiment illustrated in FIG. 5, the second material 401 is patterned and implanted to form a third dopant region 500 that extends over all of the second region 207 and the fourth region 211 while exposing the first region 205 and the third region 209. Additionally, the third dopant region 500 may further comprise a fifth region 501, a sixth region 503, and a seventh region 505, wherein the sixth region 503 extends over the first waveguide region 213 and the second waveguide region 217 between the fifth region 501 and the seventh region 505. In an embodiment the third dopant region 500 may be formed to have a sixth thickness T₆ of between about 50 nm and about 150 nm.

Looking first at the fifth region 501, the fifth region 501 provides an electrical connection between the sixth region 503 and a second contact 803 (not illustrated in FIG. 5 but illustrated and described further below with respect to FIG. 8). As such, the fifth region 501 may have a seventh width W₇ of between about 0.5 μm and about 1 μm. However, any suitable dimensions may be utilized.

Looking next at the seventh region 505, the seventh region 505 provides another electrical connection between the sixth region 503 and another second contact 803 (seen in FIG. 8). As such, the seventh region 505 may have an eighth width W₈ of between about 0.5 μm and about 1 μm. However, any suitable dimensions may be utilized.

Looking lastly at the sixth region 503, the sixth region 503 extends across the first modulated waveguide region 507 and the second modulated waveguide region 509 and connects the fifth region 501 and the seventh region 505. As such, the sixth region 503 may have a ninth width W₉ of between about 1 μm and about 4 μm. However, any suitable dimensions may be utilized.

Once the second material 401 has been patterned, a second implantation process may be performed in order to implant second dopants into the fifth region 501, the sixth region 503, and the seventh region 505. In an embodiment the second implantation process may be two or more implantations which implant second dopants within the fifth region 501, the sixth region 503 and the seventh region 505 which may be utilized along with first dopants in the underlying layers to form the tunable beam splitter 900. As such, while the precise second dopant may be dependent at least in part on the design of the tunable beam splitter 900, in some embodiments the second dopants may be n-type dopants such as phosphorous, arsenic, antimony, combinations of these, or the like. However, any suitable dopants may be used.

In an embodiment the second dopants may be implanted using an accelerator system to accelerate ions of the desired second dopants at a first dosage concentration. As such, while the precise dosage concentration utilized will depend at least in part on the fifth region 501, the sixth region 503, and the seventh region 505 and the second dopants used, in one embodiment the accelerator system may utilize an energy of between about 100 eV and about 600 eV along with a dosage concentration of about 1E13 atoms/cm² to about 1E15 atoms/cm². However, any suitable parameters may be utilized.

Additionally, the second dopants may be implanted perpendicular to the fifth region 501, the sixth region 503, and the seventh region 505 or else at, e.g., an angle of between about 0° and about 60°, from perpendicular to the fifth region 501, the sixth region 503, and the seventh region 505 and may be implanted at a temperature of between about −20° C. and about 100° C. However, any suitable parameters may be utilized.

Once of the implantations of the second implantation process may be used to implant the second dopants into the sixth region 503. In one particular embodiment the second dopants are implanted into the sixth region 503 in order to form an N+ region within the sixth region 503. As such, the second dopants may have a concentration within the sixth region 503 of between about 1e17 cm⁻³ and about 5e18 cm⁻³. However, any suitable concentration may be utilized.

Another one of the implantations of the second implantation process may be used to implant the second dopants into the fifth region 501 and the seventh region 505. In one particular embodiment the second dopants are implanted into the fifth region 501 and the seventh region 505 in order to form N++ regions. As such, the second dopants may have a concentration within the fifth region 501 and the seventh region 505 of between about 5e18 cm⁻³ and about 5e20 cm⁻³. However, any suitable concentrations may be utilized.

The second implantation process may be performed by any suitable number of implantations. For example, in one embodiment two separate implantations may be performed, in which a first implant is used in order to implant the second dopants into the fifth region 501 and the seventh region 505 while a second implant is used in order to implant the second dopants into the sixth region 503. In other embodiments, a first implant may be performed to implant the second dopants into each of the fifth region 501, the sixth region 503, and the seventh region 505 while a second implant is performed to add additional dopants into the fifth region 501 and the seventh region 505. Any suitable number of implants may be utilized, and all such implants are fully intended to be included within the scope of the embodiments.

FIG. 5 additionally illustrates that, after the second implantation process has been performed, a first portion of the sixth region 503 directly overlies the first waveguide region 213 and is separated from the first waveguide region 213 by the first dielectric material 301. Similarly, a second portion of the sixth region 503 directly overlies the second waveguide region 217 and is separated from the second waveguide region 217 by the first dielectric material 301. As such, these structures form a first modulated waveguide region 507 and a second modulated waveguide region 509.

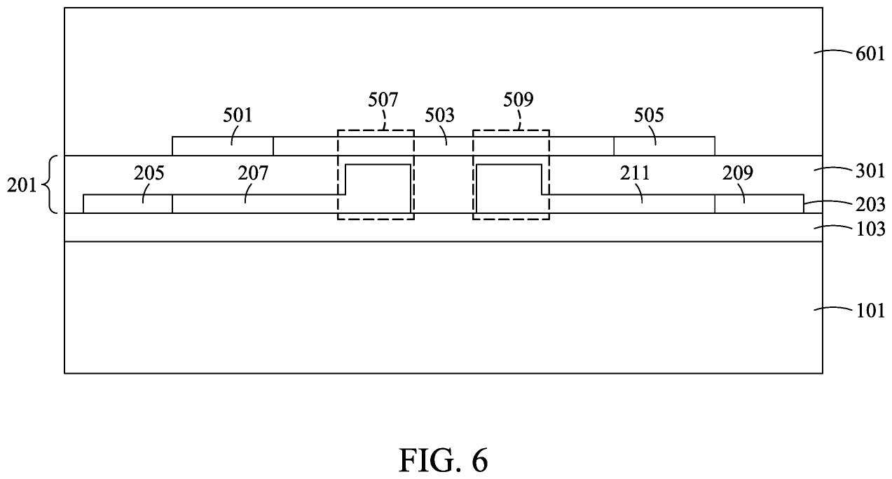

FIG. 6 illustrates a deposition of a second dielectric material 601 over the fifth region 501, the sixth region 503, the seventh region 505, and the first dielectric material 301. In an embodiment the second dielectric material 601 may be similar to the first dielectric material 301 (e.g., an oxide cladding material) and may be deposited using similar methods such as chemical vapor deposition. However, any suitable material and method of manufacture may be utilized.

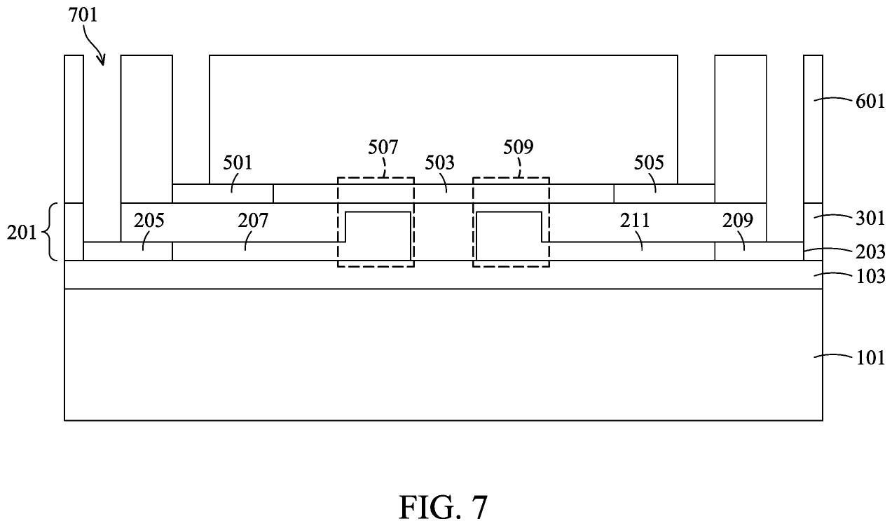

FIG. 7 illustrates a patterning of the second dielectric material 601. In an embodiment the second dielectric material 601 is patterned in order to form openings 701 to the first region 205, the fifth region 501, the seventh region 505, and the third region 209. The openings 701 may be formed using one or more photolithographic masking and etching processes. However, any suitable methods may be used to form the openings 701.

FIG. 8 illustrates a filling of the openings 701 to form first contacts 801 and second contacts 803. The first contacts 801 are formed to make electrical contacts to the first region 205 and the third region 209 while the second contacts 803 are formed to make electrical contacts to the fifth region 501 and the seventh region 505. In an embodiment the first contacts 801 and the second contacts 803 may be a conductive material such as Cu, W, Al, AlCu, Co, TaC, TaCN, TaSiN, Mn, Zr, TiN, Ta, TaN, Ni, Ti, TiAlN, Ru, Mo, or WN, although any suitable material, such as alloys of these, combinations of these, or the like, and may be deposited using a deposition process such as sputtering, chemical vapor deposition, electroplating, electroless plating, or the like, to fill and/or overfill the openings 701.

Once the material for the first contacts 801 and the second contacts 803 has been deposited, the material for the first contacts 801 and the second contacts 803 may be planarized with the second dielectric material 601. In an embodiment the material of the first contacts 801 and the second contacts 803 may be planarized using, e.g., a chemical mechanical polishing process, whereby etchants and abrasives are utilized along with a rotating platen in order to react and remove the excess material of the first contacts 801 and the second contacts 803. However, any suitable planarization process may be utilized to planarize the first contacts 801 and the second contacts 803.

FIG. 9 illustrates a top down view of the tunable beam splitter 900 illustrated in FIG. 8, with the cross-sectional view illustrated in FIG. 8 being a cross-sectional view along line A-A′ in FIG. 9. As can be seen in this top down view in FIG. 9, the first modulated waveguide region 507 and the second modulated waveguide region 509 are patterned to form a first directional coupler 901, a second directional coupler 903, and a modulating region 905.

During operation, one or more beams of light (represented in FIG. 9 by the arrow labeled 907) will enter the tunable beam splitter 900 from the first modulated waveguide region 507, the second modulated waveguide region 509, or both, and enters the first directional coupler 901. Within the first directional coupler 901 the one or more beams of light will evanescently couple between the first modulated waveguide region 507 and the second modulated waveguide region 509 and move towards the modulating region 905.

Within the modulating region 905, the first contacts 801 and the second contacts 803 are utilized in order to modulate the refractive index of the materials within the first modulated waveguide region 507 and the second modulated waveguide region 509. The desired modulation of the refractive index modifies the length of travel through the first modulated waveguide region 507 and/or the second modulated waveguide region 509. By changing the length that the light travels through the waveguide, the phase of the light passing through the waveguides can be effectively modulated relative to the incoming light beam 907.

Once the light has passed through the modulating region 905, the light will enter the second directional coupler 903. Within the second directional coupler 903, the one or more beams of light (now having had their phases modulated) will again evanescently couple between the first modulated waveguide region 507 and the second modulated waveguide region 509. During the coupling, the modulated beams of light will interfere with each other and, depending on the desired design of the tunable beam splitter 900, the modulated light will split into multiple beams that can be directed into different waveguides as the light passes out of the second directional coupler 903.

By forming the tunable beam splitter 900 as described, a common polysilicon ground design can be utilized, allowing for an increased ability to scale the number of contacts, such as the first contacts 801 and the second contacts 803. Additionally, the use of the common polysilion ground design enables the active region to be extended just beyond the modulating region 905 and into the regions of the first directional coupler 901 and the second directional couplers 903. As such, a same modulation efficiency can be achieved with a smaller unit cell than other beam splitters. Additionally, the large distance between the polysilicon sidewall and optical waveguide regions minimizes the influence of polysilicon induced scattering losses. Finally, by extending the active region to the regions of the first directional coupler 901 and the second directional coupler 903 provides extra electro-optical tuning ranges and better design flexibility.

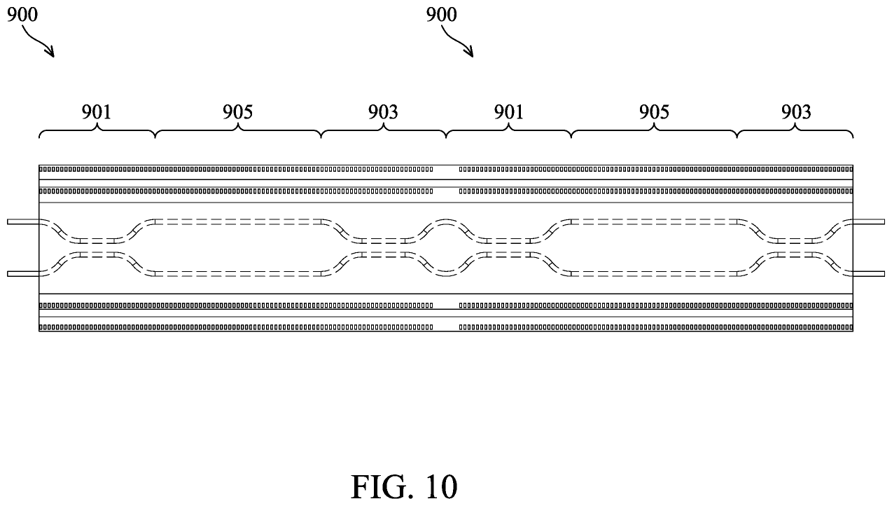

FIG. 10 illustrates another embodiment in which the tunable beam splitter 900 may be utilized. In the embodiment illustrated in FIG. 10, however, instead of forming the tunable beam splitter 900 as an individual device, multiple ones of the tunable beam splitter 900 may be formed in series, such as the two tunable beam splitters 900 that are illustrated in FIG. 10. In such an embodiment each of the individual tunable beam splitters 900 may be formed as described above with respect to FIGS. 1-9, and may be the same or different from each other. All such configurations, and any suitable number of tunable beam splitters 900 may be utilized.

In an embodiment, a method of manufacturing an optical device includes: forming a first dopant region over a substrate, the first dopant region comprising a first waveguide and a second waveguide; depositing a cladding material over the first waveguide and the second waveguide; and forming a second dopant region overlying the first waveguide and the second waveguide, wherein the forming the second dopant region comprises forming a first region extending over both the first waveguide and the second waveguide, the first region having a constant concentration of a first dopant. In an embodiment the forming the second dopant region further includes: forming a second region extending away from the first region, the second region having a higher concentration of the first dopant than the first region, and forming a third region extending away from the first region, the third region having a higher concentration of the first dopant than the first region. In an embodiment the method further includes: forming a first contact to the second region; and forming a second contact to the third region. In an embodiment the forming the first dopant region comprises forming a connective region in physical contact with the first waveguide, the connective region having a smaller thickness than the first waveguide. In an embodiment the forming the first dopant region comprises forming a first contact region in physical contact with the connective region, the first contact region having a larger concentration of a second dopant than the connective region. In an embodiment the first dopant is an n-type dopant and the second dopant is a p-type dopant. In an embodiment the optical device is a beam splitter.

In another embodiment, a method of manufacturing an optical device includes: forming a first coupler, a first modulating region, and a second coupler using a first waveguide and a second waveguide; and forming a first polysilicon material overlying both the first waveguide and the second waveguide, the first polysilicon material having a constant concentration of a first dopant, the first polysilicon material extending over the first coupler. In an embodiment the method further includes forming a third coupler, a second modulating region, and a fourth coupler in series with the first coupler, the first modulating region, and the second coupler. In an embodiment the first waveguide comprises a P+ region. In an embodiment the first polysilicon material comprises a N+ region. In an embodiment the method further includes forming a first contact to a N++ region, the N++ region electrically connecting the first polysilicon material to the first contact. In an embodiment the method further includes forming a second contact to a P++ region, the P++ region electrically connecting the first waveguide to the second contact. In an embodiment the second contact is located further from the first waveguide than the first contact.

In yet another embodiments, a optical device includes: a first waveguide over a substrate; a second waveguide over the substrate, wherein the first waveguide and the second waveguide form a first coupler, a modulation region, and a second coupler; and a first polysilicon material overlying both the first waveguide and the second waveguide, the first polysilicon material having a constant concentration of a first dopant, the first polysilicon material extending over the first coupler. In an embodiment the first waveguide comprises a P+ region and the first polysilicon material comprises a N+ region. In an embodiment the optical device further includes a first contact in physical contact with a P++ region, the P++ region in electrical connection with the first waveguide. In an embodiment the optical device further includes a second contact in physical contact with an N++ region, the N++ region in electrical connection with the first polysilicon material. In an embodiment the first contact is located on an opposite side of the second contact from the N++ region. In an embodiment the first waveguide is adjacent to a P+ region, the P+ region having a smaller thickness than the first waveguide.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of manufacturing an optical device, the method comprising:
forming a first dopant region over a substrate, the first dopant region comprising a first waveguide and a second waveguide;
depositing a cladding material over the first waveguide and the second waveguide; and
forming a second dopant region overlying the first waveguide and the second waveguide, wherein the forming the second dopant region comprises forming a first region extending over both the first waveguide and the second waveguide, the first region having a constant concentration of a first dopant.

2. The method of claim 1, wherein the forming the second dopant region further comprises:
forming a second region extending away from the first region, the second region having a higher concentration of the first dopant than the first region; and
forming a third region extending away from the first region, the third region having a higher concentration of the first dopant than the first region.

3. The method of claim 2, further comprising:
forming a first contact to the second region; and
forming a second contact to the third region.

4. The method of claim 3, wherein the forming the first dopant region comprises forming a connective region in physical contact with the first waveguide, the connective region having a smaller thickness than the first waveguide.

5. The method of claim 4, wherein the forming the first dopant region comprises forming a first contact region in physical contact with the connective region, the first contact region having a larger concentration of a second dopant than the connective region.

6. The method of claim 5, wherein the first dopant is an n-type dopant and the second dopant is a p-type dopant.

7. The method of claim 1, wherein the optical device is a beam splitter.

8. A method of manufacturing an optical device, the method comprising:
forming a first coupler, a first modulating region, and a second coupler using a first waveguide and a second waveguide; and
forming a first polysilicon material overlying both the first waveguide and the second waveguide, the first polysilicon material having a constant concentration of a first dopant, the first polysilicon material extending over the first coupler.

9. The method of claim 8, further comprising forming a third coupler, a second modulating region, and a fourth coupler in series with the first coupler, the first modulating region, and the second coupler.

10. The method of claim 8, wherein the first waveguide comprises a P+ region.

11. The method of claim 10, wherein the first polysilicon material comprises an N+ region.

12. The method of claim 11, further comprising forming a first contact to a N++ region, the N++ region electrically connecting the first polysilicon material to the first contact.

13. The method of claim 12, further comprising forming a second contact to a P++ region, the P++ region electrically connecting the first waveguide to the second contact.

14. The method of claim 13, wherein the second contact is located further from the first waveguide than the first contact.

15. An optical device comprising:
a first waveguide over a substrate;
a second waveguide over the substrate, wherein the first waveguide and the second waveguide form a first coupler, a modulation region, and a second coupler; and
a first polysilicon material overlying both the first waveguide and the second waveguide, the first polysilicon material having a constant concentration of a first dopant, the first polysilicon material extending over the first coupler.

16. The optical device of claim 15, wherein the first waveguide comprises a P+ region and the first polysilicon material comprises an N+ region.

17. The optical device of claim 16, further comprising a first contact in physical contact with a P++ region, the P++ region in electrical connection with the first waveguide.

18. The optical device of claim 17, further comprising a second contact in physical contact with an N++ region, the N++ region in electrical connection with the first polysilicon material.

19. The optical device of claim 18, wherein the first contact is located on an opposite side of the second contact from the N++ region.

20. The optical device of claim 15, wherein the first waveguide is adjacent to a P+ region, the P+ region having a smaller thickness than the first waveguide.
